(19) United States
(12) Patent Application Publication
(10) Pub. No.: US 2004/0126922 A1
(43) Pub. Date: Jul. 1, 2004

(54) Photo diode, opto-electronic integrated circuit device comprising the same, and method for manufacturing the same

(76) Inventors: Joo Yul Ko, Yongin (KR); Sang Suk Kim, Suwon (KR); Deuk Hee Park, Seoul (KR); Kyoung Soo Kwon, Suwon (KR)

Correspondence Address: LOWE HAUPTMAN GOPSTEIN GILMAN & BERNER, LLP, Suite 310, 1700 Diagonal Road, Alexandria, VA, 22314, US

(21) Appl. No.: 10/610,678

(22) Filed: Jul. 2, 2003

(30) Foreign Application Priority Data
Dec. 26, 2002 (KR) 2002-83866

(51) Int. Cl. H01L 21/00; H01L 31/0328

(52) U.S. Cl. 438/57

(57) ABSTRACT

Disclosed are a photo diode sensing a short-wavelength light in a blue band, an opto-electronic integrated circuit device comprising the photo diode, and a method of manufacturing the photo diode. The method for manufacturing the photo diode, comprising the steps of: preparing a silicon substrate; forming a first conductive impurity region at a first region on the silicon substrate; forming a second conductive impurity region at a second region on the silicon substrate, said second region being separated from the first region; and forming a porous silicon layer by chemically etching a surface of the second conductive impurity region.

### BACKGROUND OF THE INVENTION

1. Field of the Invention

The present invention relates to a photo diode, an opto-electronic integrated circuit device comprising the same, and a method for manufacturing the same, and more particularly to a photo diode comprising a porous silicon layer formed by chemical etching so as to sense short-wavelength light, an opto-electronic integrated circuit device comprising the photo diode, and a method for manufacturing the photo diode.

2. Description of the Related Art

Recently, with the evolution of recording media, storage devices, particularly optical storage devices have been rapidly developed. The optical storage device tends to convert a compact disk into a DVD (digital video disk). Further, due to the limited available capacity of the optical storage device, current optical storage devices increasingly need to receive a short wavelength so as to obtain a high-density record.

Generally, the usable wavelengths of optical storage devices have changed from approximately 750 nm to approximately 650 nm, and then has changed again to a blue band (approximately 405 nm). Therefore, a photo diode used in a head of an optical pick-up device must be changed so as to be suitably used in a blue band or a short wavelength band corresponding to an ultraviolet light.

For this purpose, in order to obtain a photo diode suitable for short wavelengths, a compound semiconductor having an energy band gap corresponding to such short wavelength is conventionally used. As the compound semiconductor, there are Cd₄SiS₆, Cd₄GeS₆, ZnS, etc. The compound semiconductor has an energy band gap of approximately 3.7˜5 eV, and the peak of sensitivity of the compound semiconductor occurs in approximately 340˜470 nm.

However, it is difficult to manufacture the compound semiconductor and to substantially form a photo diode made of the compound semiconductor.

The aforementioned compound semiconductor has problems as follows.

Generally, when an opto-electronic integrated circuit (hereinafter referred to as an “OEIC”, or also a “photodiode integrated circuit (PDIC)”) is manufactured by integrating the photo diode and peripheral circuits, the peripheral integrated circuits for amplifying a signal outputted from the photo diode and converting the signal must be made of a semiconductor material such as Si. Therefore, in case the compound semiconductor being suitable for short-wavelength light is used to form a photo diode, it is difficult to integrate the photo diode and the peripheral circuit portion formed using the conventional silicon substrate into the same semiconductor chip.

On the other hand, in case a photo diode is manufactured using Si, the integration of the photo diode with other peripheral circuits is easy. A usable wavelength of the photo diode made of Si is approximately 450 nm to 1,100 nm. However, since the optical length of the photo diode in the short wavelength corresponding to the ultraviolet light is thousands of A, substantially the usable wavelength of the photo diode is 780 nm or 650 nm.

FIG. 1 is a schematic cross-sectional view of a conventional silicon photo diode. FIG. 1 shows a substrate structure comprising a P-type silicon substrate 11 and an N-type intrinsic epitaxial layer 15 formed thereon. Further, a P-type buried layer is formed between the P-type silicon substrate 11 and the N-type intrinsic epitaxial layer 15. The intrinsic epitaxial layer 15 is a silicon layer, which is not coated with any impurity or is low-density coated with an N-type impurity.

The silicon semiconductor substrate is divided into two regions (A1) and (A2). P⁺-type wells 17 are formed on designated regions of the epitaxial layer 15 and N⁺-type impurity regions 18 are formed between the neighboring P⁺-type wells 17. Thereby, a PIN(P-Intrinsic-N) photo diode is produced. The portion shown in FIG. 1 is an enlarged view of a device region comprising two fingers of an interdigitated comb type structure of two electrodes of the photo diode.

Since the above photo diode is made of silicon, light injected into a depletion layer region formed within the epitaxial layer 15 along a junction of the N⁺-type impurity region 19 and the epitaxial layer 15 is a long wavelength in the range of approximately 650˜780 nm.

Since the optical length of the silicon material in 405 nm is thousands of Å, the light is absorbed by the photo diode mainly in its outer surface. Therefore, it is difficult to inject the light into the junction of the N⁺-type impurity region 19 and the epitaxial layer 15. Such photo diode made of silicon has low photo conversion efficiency in short wavelengths.

As shown in FIG. 1, although the photo diode having the interdigitated comb type structure is manufactured so as to improve the photo conversion efficiency and to maximize the optical absorption at the surface of the photo diode, the aforementioned conventional photo diode still has poor photo conversion efficiency in short wavelengths.

Therefore, there are required a photo diode being made of silicon so as to be manufactured simultaneously with signal processing circuits and having high photo conversion efficiency in a blue band or short-wavelength light corresponding to an ultraviolet band, and a method for manufacturing the same.

### SUMMARY OF THE INVENTION

Therefore, the present invention has been made in view of the above problems, and it is an object of the present invention to provide a photo diode comprising a porous silicon layer formed at a light-receiving region on a surface of a silicon semiconductor so as to convert short-wavelength light in a blue band into long-wavelength light being transmittable by silicon, and an opto-electronic integrated circuit device provided with the photo diode, thereby improving photo conversion efficiency in the short-wavelength light.

It is another object of the present invention to provide a method for manufacturing a photo diode comprising a step of forming a porous silicon layer by chemical etching so as to convert short-wavelength light in a blue band into a desired long-wavelength light, thereby protecting other devices of an integrated circuit from electrical damage.

In accordance with one aspect of the present invention, the above and other objects can be accomplished by the provision of a method for manufacturing a photo diode, comprising the steps of:

preparing a silicon substrate;

forming a first conductive impurity region at a first region on the silicon substrate;

forming a second conductive impurity region at a second region on the silicon substrate, the second region being separated from the first region; and

forming a porous silicon layer by chemically etching a surface of the second conductive impurity region.

Preferably, a stain etching process may be used in the step of forming the porous silicon layer.

Further, preferably, the step of forming the porous silicon layer may include the sub-steps of: forming a photoresist on the silicon substrate so as to expose the surface of the second conductive impurity region; and etching the surface of the second conductive impurity region with an etching solution via the photoresist.

Preferably, the etching solution may be a compound solution containing HF:HNO₃:H₂O in a ratio of approximately 1:3:5.

In accordance with another aspect of the present invention, there is provided a photo diode comprising:

a silicon substrate;

a first conductive impurity region formed at a first region on the silicon substrate;

a second conductive impurity region formed at a second region on the silicon substrate, the second region being separated from the first region; and

a porous silicon layer being formed by chemically etching a surface of the second conductive impurity region and serving to convert a wavelength of incident light in an ultraviolet light band into a wavelength in a visible light band so as to be transmitted by the silicon substrate.

In accordance with yet another aspect of the present invention, there is provided an opto-electronic integrated circuit formed on a silicon semiconductor substrate, comprising:

a photo diode formed at one region on the silicon semiconductor substrate, including:

a silicon substrate;

a first conductive impurity region formed at a first region on the silicon substrate;

a second conductive impurity region formed at a second region on the silicon substrate, the second region being separated from the first region; and

a porous silicon layer being formed by chemically etching a surface of the second conductive impurity region and serving to convert a wavelength of incident light in an ultraviolet light band into a wavelength in a visible light band so as to be transmitted by the silicon substrate; and

an integrated circuit portion formed at the other region on the silicon substrate so as to amplify a signal outputted from a cell of the photo diode and process the amplified signal.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of a conventional PIN photo diode;

FIG. 2 is a cross-sectional view of a photo diode in accordance with the present invention;

FIG. 3 is a graph showing photoluminescence characteristics of a porous silicon employed by the present invention;

FIG. 4 is a graph comparatively illustrating sensitivities of the conventional photo diode and the photo diode of the present invention to short-wavelength light in a blue band; and

FIGS. 5a to 5d are cross-sectional views illustrating a process for manufacturing the photo diode in accordance with the present invention.

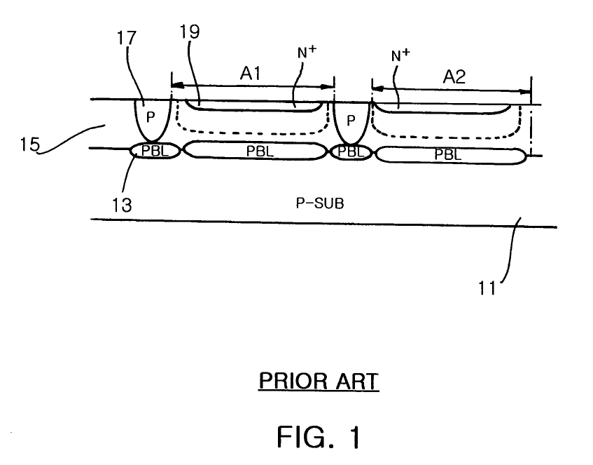

### DESCRIPTION OF THE PREFERRED EMBODIMENTS

Now, preferred embodiments of the present invention will be described in detail with reference to the annexed drawings.

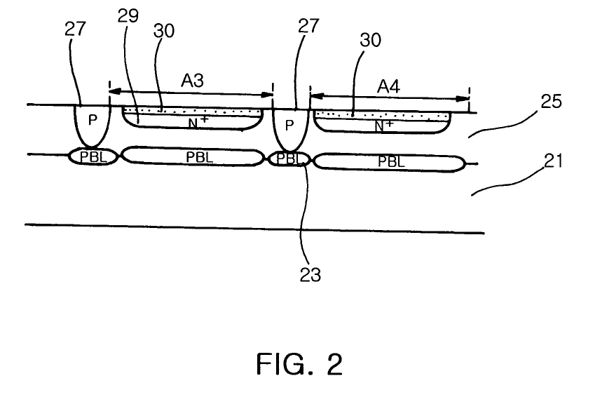

FIG. 2 is a cross-sectional view of a PIN photo diode in accordance with the present invention. The portion shown in FIG. 2 is a part of the PIN photo diode having a interdigitated comb type structure.

FIG. 2 shows a substrate structure comprising a P-type silicon substrate 21 and an intrinsic epitaxial layer 25 formed thereon. The substrate 21 is divided into two regions (A3) and (A4), thereby forming two PIN photo diodes. Although the two PIN photo diodes are shown in FIG. 2, a plurality of PIN photo diodes are substantially formed.

Further, a P-type buried layer 23 is formed between the P-type silicon substrate 21 and the intrinsic epitaxial layer 25. Generally, the intrinsic epitaxial layer 25 is a low-density N-type epitaxial layer. P⁺-type wells 27 are formed on the intrinsic epitaxial layer 25, and N⁺-type impurity regions 29 are formed between the neighboring P⁺-type wells 27. Thereby, a PIN(P-Intrinsic-N) photo diode is completed.

A depletion region is formed within the intrinsic epitaxial layer 25 along a junction between the N⁺-type impurity region 29 and the intrinsic epitaxial layer 25. As external light having a designated wavelength is incident on the depletion region, the PIN photo diode generates a designated current.

In the present invention, a porous silicon layer 30 is additionally formed on the surface of the N⁺-type impurity region 29. The porous silicon layer 30 converts light having a short wavelength of approximately 405 nm into light having a long wavelength of approximately 600˜650 nm using a photo luminescence (PL) effect. Since the short-wavelength light is converted into the long-wavelength light by the porous silicon layer 30, the converted long-wavelength light is incident on the depletion layer via the below N⁺-type impurity region 29. Thereby, the photo diode of the present invention generates a photocurrent.

Herein, the porous silicon layer 30 is formed by a chemical process. Conventionally, a porous silicon layer is formed by an anodization process. The anodization process is an electromechanical method for forming the porous silicon layer, in which a designated voltage is provided in addition to an etching solution.

Therefore, when peripheral integrated circuits are formed on a silicon semiconductor substrate simultaneously with the photo diode, the conventional anodization process for forming the porous silicon layer 30 causes fatal damage to the peripheral integrated circuits. Therefore, the present invention employs the porous silicon layer 30 formed only by the chemical process.

As described above, since the photo diode made of silicon of the present invention is easily formed on the silicon substrate simultaneously with integrated circuits for processing a signal outputted from the photo diode, and converts short-wavelength light in a blue band into a silicon-transmittable long-wavelength light by means of the porous silicon layer 30, the photo diode has excellent sensitivity to short wavelengths.

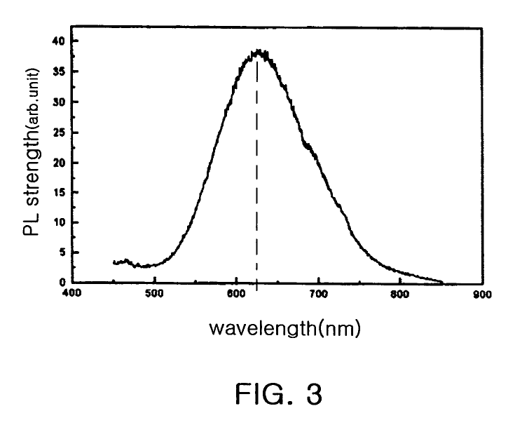

A function of the porous silicon layer of the present invention for converting short-wavelength light into long-wavelength light is described in FIG. 3. A graph of FIG. 3 shows the strength of photo luminescence (PL) in a short wavelength of approximately 395 nm.

As shown in FIG. 3, when light having a short wavelength of 395 nm is incident on the porous silicon layer, the porous silicon layer emits light having a long wavelength of approximately 600˜650 nm by means of the photo luminescence (PL) effect. That is, the porous silicon layer serves as a filter for transmitting a long wavelength in a visible light band of 600˜650 nm.

Therefore, when the porous silicon layer is formed on the surface of the N-type impurity region serving as a light-receiving surface, the incident light having the short wavelength can be converted into light having a long wavelength so as to be sensible by the photo diode made of silicon. As a result, the photo diode made of silicon can sense the short-wavelength light in a blue band, and then generate a photocurrent according to the quantity of the sensed light.

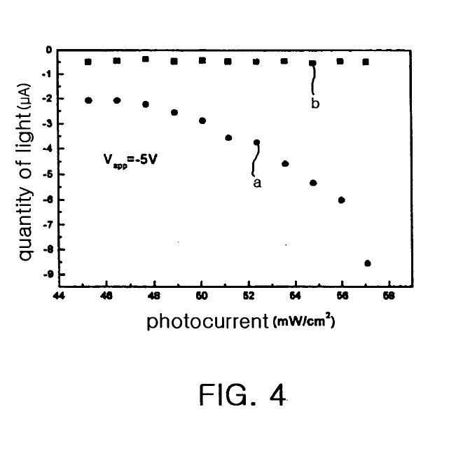

FIG. 4 is a graph comparatively illustrating sensitivities of the conventional photo diode and the photo diode of the present invention. The graph of FIG. 4 is obtained by measuring photocurrents generated by the conventional photo diode and the photo diode of the present invention, when the quantity of short-wavelength light of approximately 405 nm is increased in the range of approximately 45˜57 mW/cm².

As shown in FIG. 4, in a curve (b) of the conventional photo diode, the conventional photo diode little generates a photocurrent in the initial quantity of light of 45 mW/cm². Also, the conventional photo diode little generates a photocurrent in the increased quantity of light of 57 mW/cm².

As described above, since the optical length of the silicon material is thousands of Å in 405 nm, the light is absorbed by the photo diode mainly around its surface.

On the other hand, in a curve (a) of the silicon photo diode of the present invention, the silicon photo diode of the present invention generates a photocurrent of approximately −2 A in the initial quantity of light of 45 mW/cm². The greater the quantity of the light, the higher the photocurrent. Therefore, the silicon photo diode of the present invention generates a photocurrent of approximately −6 A in the increased quantity of light of 57 mW/cm².

As described above, the photo diode of the present invention generates the photocurrent, which is gradually increased according to the increase of the quantity of light, even in short-wavelength light of approximately 405 nm. That is, in the photo diode of the present invention, the porous silicon layer converts the short-wavelength light into a visible light of approximately 600˜650 nm so as to be sensed by the silicon photo diode. Thereby, the photo diode of the present invention has excellent photo conversion efficiency.

Further, the present invention provides an opto-electronic integrated circuit.

Generally, the opto-electronic integrated circuit comprises a photo diode and an integrated circuit portion, formed on the same silicon semiconductor substrate. The integrated circuit portion is a signal processing circuit for amplifying a signal outputted from the photo diode and converting the amplified analog signal into a digital signal so as to be easily processed, and may be various semiconductor devices formed on the silicon substrate such as a bipolar transistor, a MOSFET and/or a CMOS.

In order to minimize the opto-electronic integrated circuit, preferably, the integrated circuit portion and the photo diode are simultaneously formed on the silicon semiconductor substrate. However, the conventional photo diode made of silicon has a problem of low photo conversion efficiency in a short wavelength.

In order to solve the above problem, the present invention further provides a photo-electronic integrated circuit device comprising a photo diode being suitable for a short wavelength. The photo-electronic integrated circuit device of the present invention comprises a photo diode and an integrated circuit portion formed on the same silicon semiconductor substrate. Herein, the photo diode includes a silicon substrate, a first conductive impurity region formed on a first region of the silicon substrate, a second conductive impurity region formed on a second region of the silicon substrate, and a porous silicon layer formed on the surface of the second conductive impurity region by chemical etching so as to convert an incident wavelength in a ultraviolet light band into a wavelength in a visible light band and then to transmit the converted wavelength.

As described above, the photo diode provided by the opto-electronic integrated circuit device of the present invention comprises the porous silicon layer formed on the surface of the second conductive impurity region serving as the light-receiving surface by chemical processing, thereby converting an incident short-wavelength light into long-wavelength light so as to be sensed by the photo diode made of silicon. As a result, the photo diode of the above-described opto-electronic integrated circuit can sense the short-wavelength light.

Particularly, the porous silicon layer of the photo diode in the opto-electronic integrated circuit of the present invention must be formed by chemical processing. Differently from the present invention, in case the porous silicon layer is formed by an anodization process, a step of applying a designated voltage is required in addition to a step of providing an etching solution. Such step of applying the designated voltage may cause undesirable damage to the peripheral integrated circuits already formed on the substrate simultaneously with the photo diode. Therefore, the porous silicon layer formed on the light-receiving surface of the photo diode in the opto-electronic integrated circuit device of the present invention is limited to a porous silicon layer obtained by chemical etching.

As described above, since the opto-electronic integrated circuit of the present invention comprises the photo diode being not made of compound semiconductor material but being made only of silicon semiconductor material so as to sense short-wavelength light, the integrated circuit portion and the photo diode are simultaneously formed on the same silicon substrate.

Further, since the porous silicon layer for converting short-wavelength light into a visible light so as to be detectable by the silicon photo diode is formed in the opto-electronic integrated circuit of the present invention only by chemical processing, the step of applying voltage used in electrochemical processing such as the anodization process is omitted. Therefore, the opto-electronic integrated circuit of the present invention has a simplified manufacturing process and protects peripheral devices from electrical damage.

Moreover, the present invention further provides a method for manufacturing a photo diode. The method for manufacturing the photo diode of the present invention is advantageous in terms of forming an opto-electronic integrated circuit simultaneously comprising the photo diode and an integrated circuit portion for processing a signal outputted from the photo diode.

With this view, the method for manufacturing the photo diode of the present invention will be described with reference to a process for manufacturing an opto-electronic integrated circuit comprising the photo diode.

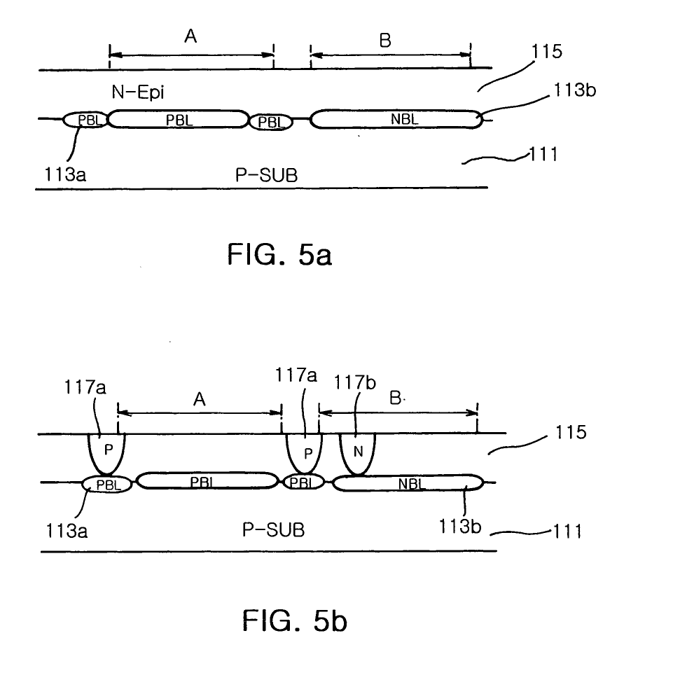

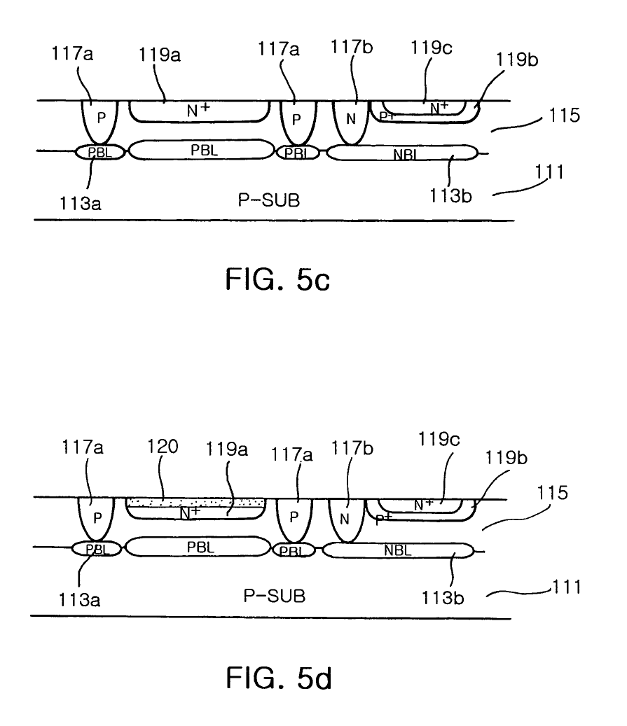

FIGS. 5a to 5d are cross-sectional views illustrating a process for manufacturing the photo diode in accordance with the present invention. The process for manufacturing the photo diode of FIGS. 5a to 5d is described together with the process for manufacturing an opto-electronic integrated circuit.

Although the process for manufacturing the opto-electronic integrated circuit comprises a step of forming a peripheral integrated circuit portion of the opto-electronic integrated circuit as a NPN-type bipolar transistor, the peripheral integrated circuit portion may be formed as various devices by similar steps.

First, as shown in FIG. 5a, a low-density doped P-type silicon substrate 111 is prepared. A low-density N-type epitaxial layer 115 and P-type and N-type buried layers 113a and 113b are formed on the upper surface of the P-type silicon substrate 111. The upper surface of the epitaxial layer 115 is divided into a region (A) where a photo diode is formed, and a region (B) where an integrated circuit portion such as the bipolar transistor is formed.

As shown in FIG. 5b, a high-density P-type well 117a is formed on both sides of the photo diode region (A) on the N-type epitaxial layer 115, and an N-type well 117b having a density higher than that of the N-type epitaxial layer 115 is formed at the integrated circuit region (B).

The aforementioned P-type and N-type wells 117a and 117b are easily formed by a photolithography step in a conventional semiconductor manufacturing process known in the art.

As shown in FIG. 5c, a high-density P-type impurity region 119b is formed in the low-density N-type epitaxial layer 115 at the integrated circuit region (B). Then, a N-type impurity region 119c is formed within the high-density P-type impurity region 119b, and simultaneously a high-density N-type impurity region 119a is formed in the N-type epitaxial layer 115 at the photo diode region (A).

In this step, the high-density impurity regions 119a and 119c respectively formed at the photo diode region (A) and the integrated circuit region (B) may be separately formed by different steps. However, in case the high-density impurity regions 119a and 119c are doped at the same density, the high-density impurity regions 119a and 119c may be simultaneously formed by one step.

After the above step is finished, as shown in FIG. 5c, a photo diode and an NPN-type bipolar transistor, having a structure similar to that of the conventional opto-electronic integrated circuit, are formed.

In accordance with the present invention, as shown in FIG. 5d, a step of forming a porous silicon layer 120 on the surface of the N-type impurity region 119a of the photo diode is additionally carried out. With reference to FIG. 5d, the porous silicon layer 120 is formed along the surface of the N-type impurity region 119a of the photo diode.

In this step, the surface of the N-type impurity region 119a is processed by chemical etching, and thus the porous silicon layer 120 is formed on the surface of the N-type impurity region 119a.

Preferably, the chemical etching for forming the porous silicon layer 120 used in the above step is a stain etching process.

Generally, the stain etching process does not require an electrical action as in the anodization process, but depends only on the chemical etching process under a fluorescent lamp atmosphere so as to form the porous silicon layer.

Hereinafter, a process for applying the aforementioned stain etching to the forming of the porous silicon layer 120 of the present invention will be described in detail.

The stain etching process employed by the step of forming the porous silicon layer 120 of the present invention starts with a step of forming a photoresist on the device so as to expose the surface of the second conductive impurity region (119a in FIG. 5c).

Instead of the photoresist used in the stain etching process, the conventional anodization process uses a SiN₄ mask. Then, as a fluorescent light is irradiated thereon, the surface of the second conductive impurity region is etched with an etching solution through the photoresist. Preferably, as the etching solution, a compound solution containing HF:HNO₃:H₂O in the ratio of approximately 1:3:5 is used. The surface of the second conductive impurity region is etched with the above compound solution, thereby being converted into a porous silicon layer.

Since the porous silicon layer is formed by chemical processing, the method for manufacturing the photo diode of the present invention protects integrated circuit devices from conventional damage by the electrical action of the anodization.

As apparent from the above description, the present invention provides a photo diode comprising a porous silicon layer formed on a light-receiving surface by chemical processing without the use of a separate compound semiconductor substrate so as to convert short-wavelength light into long-wavelength light being transmittable by a silicon semiconductor substrate.

Further, the present invention provides an opto-electronic integrated circuit device comprising a photo diode and an integrated circuit portion simultaneously formed on the same silicon substrate, and a porous silicon layer formed on the photo diode by chemical processing, thereby protecting the integrated circuit portion from electrical damage.

Moreover, the present invention provides a method for manufacturing a photo diode.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing a photo diode, comprising the steps of:
preparing a silicon substrate;
forming a first conductive impurity region at a first region on the silicon substrate;
forming a second conductive impurity region at a second region on the silicon substrate, said second region being separated from the first region; and
forming a porous silicon layer by chemically etching a surface of the second conductive impurity region.

2. The method for manufacturing a photo diode as set forth in claim 1,
wherein a stain etching process is used in the step of forming the porous silicon layer.

3. The method for manufacturing a photo diode as set forth in claim 2,
wherein the step of forming the porous silicon layer includes the sub-steps of:
forming a photoresist on the silicon substrate so as to expose the surface of the second conductive impurity region; and
etching the exposed surface of the second conductive impurity region with an etching solution.

4. The method for manufacturing a photo diode as set forth in claim 3,
wherein the etching solution is a compound solution containing HF:HNO₃:H₂O in a ratio of approximately 1:3:5.

5. A photo diode comprising:
a silicon substrate;
a first conductive impurity region formed at a first region on the silicon substrate;
a second conductive impurity region formed at a second region on the silicon substrate, said second region being separated from the first region; and
a porous silicon layer being formed by chemically etching a surface of the second conductive impurity region and serving to convert a wavelength of incident light in an ultraviolet light band into a wavelength in a visible light band so as to be transmitted by the silicon substrate.

6. An opto-electronic integrated circuit formed on a silicon semiconductor substrate, comprising:
a photo diode formed at one region on the silicon semiconductor substrate, including:
a silicon substrate;
a first conductive impurity region formed at a first region on the silicon substrate;
a second conductive impurity region formed at a second region on the silicon substrate, said second region being separated from the first region; and
a porous silicon layer being formed by chemically etching a surface of the second conductive impurity region and serving to convert a wavelength of incident light in an ultraviolet light band into a wavelength in a visible light band so as to be transmitted by the silicon substrate; and
an integrated circuit portion formed at the other region on the silicon substrate so as to amplify a signal outputted from a cell of the photo diode and process the amplified signal.
